(19) United States
(12) Patent Application Publication
(10) Pub. No.: US 2008/0191335 A1
(43) Pub. Date: Aug. 14, 2008

(54) CMOS IMAGE SENSOR CHIP SCALE PACKAGE WITH DIE RECEIVING OPENING AND METHOD OF THE SAME

(75) Inventors: Wen-Kun Yang, Hsin-Chu City (TW); Jui-Hsien Chang, Jhudong Township (TW); Hsien-Wen Hsu, Lujhou City (TW); Diann-Fang Lin, Hukou Township (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/755,293

(22) Filed: May 30, 2007

Related U.S. Application Data
(63) Continuation-in-part of application No. 11/703,663, filed on Feb. 8, 2007.

(51) Int. Cl. H01L 23/02; H01L 21/00

(52) U.S. Cl. 257/680; 438/113; 257/E23.18; 257/E21.001

(57) ABSTRACT

The present invention provides a structure of package comprising a substrate with a die through hole and a contact through holes structure formed there through, wherein a terminal pad is formed under the contact through hole structure and a contact pad is formed on a upper surface of the substrate. A die having a micro lens area is disposed within the die through hole by adhesion. A thick dielectric layer is formed on the die and the substrate except the micro lens, bonding pads and contact pads. A wire bonding is formed on the die and the substrate, wherein the wire bonding is coupled to the die and the contact pad. And core paste is filled into the gap between the die edge and the sidewall of the die through hole of the substrate. A transparent cover is disposed on the die and the thick dielectric layer by adhesion to create a gap between the transparent cover.

### RELATED APPLICATIONS

The present application is a continuation-in-part of co-pending application Ser. No. 11/703,663 entitled “Image Sensor Package with Die Receiving Opening and Method of the Same” filed on Feb. 8, 2007, and commonly assigned to the present assignee, the contents of which are herein incorporated by reference.

### FIELD OF THE INVENTION

This invention relates to a structure of panel level package (PLP), and more particularly to a substrate with die receiving opening to receive an image sensor die for PLP.

### DESCRIPTION OF THE PRIOR ART

In the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip.

Furthermore, because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dice). Generally, after completion of all assembling processes or packaging processes, individual semiconductor packages are separated from a wafer having a plurality of semiconductor dies. The wafer level package has extremely small dimensions combined with extremely good electrical properties.

WLP technique is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Though the advantages of WLP technique mentioned above, some issues still exist influencing the acceptance of WLP technique. For example, although utilizing WLP technique can reduce the CTE mismatch between IC and the interconnecting substrate, as the size of the device minimizes, the CTE difference between the materials of a structure of WLP becomes another critical factor to mechanical instability of the structure. Furthermore, in this wafer-level chip-scale package, a plurality of bond pads formed on the semiconductor die is redistributed through conventional redistribution processes involving a redistribution layer into a plurality of metal pads in an area array type. Solder balls are directly fused on the metal pads, which are formed in the area array type by means of the redistribution process. Typically, all of the stacked redistribution layers are formed over the built-up layer over the die. Therefore, the thickness of the package is increased. This may conflict with the demand of reducing the size of a chip.

Therefore, the present invention provides a FO-WLP structure without stacked built-up layer and RDL to reduce the package thickness to overcome the aforementioned problem and also provide the better board level reliability test of temperature cycling.

### SUMMARY OF THE INVENTION

The present invention provides a structure of package comprising a substrate with a die through hole and a contact through holes structure formed there through, wherein terminal pads are formed under the contact through holes structure and contact pads are formed on a upper surface of the substrate. A die having a micro lens area is disposed within the die through hole by adhesion. A thick dielectric layer is formed on the active surface of the die and upper surface of the substrate except the micro lens, bonding pads and contact pads. A wire bonding is formed on the die and the substrate, wherein the wire bonding is coupled to bonding pads of the die and the contact pads of the substrate. A core paste (die attached material) is filled into the gap between the die edge, die back site and the sidewall of the die through hole of the substrate. A transparent cover is disposed on the die and the thick dielectric layer by adhesion to create a gap between the transparent cover. Conductive bumps are coupled to the terminal pads as optional process.

It should be noted that the present invention provide a method for forming semiconductor device, such as CMOS Image Sensor (CIS), package. Firstly, the process includes providing a substrate with a die through hole and a contact through holes structure formed there through on a tool, wherein the terminal pads are formed under said contact through holes structure and a contact pads are formed on an upper surface of said substrate. Subsequently, a pick and place fine alignment system is used to re-distribute known good dice image sensor chips on the tool with desired pitch. A core paste is filled into the gap between the die edge, die back site and the sidewall of the die through hole, and vacuum curing then separating the tool. Next, the thick dielectric layer is formed on the panel and opening the micro lens area, bonding pads area and contact pads area. A wire bonding is formed to couple between the chip and contact pad of the substrate. And then, a transparent cover with inscribed lines is bonded on a panel over the thick dielectric layer. Next, cutting the panel from the terminal metal site of the substrate is performed. Finally, semiconductor device package is singulated into individual units by employing breaking the transparent cover along the scribe lines.

The image sensor chips has been coated the protection layer (film) on the micro lens area; the protection layer (film) with the properties of water repellent and oil repellent that can away the particles contamination on the micro lens area; the thickness of protection layer (film) preferably around 0.1 um to 0.3 um and the reflection index close to air reflection index 1. The process can be executed by SOG (spin on glass) skill and it can be processed in silicon wafer form. The materials of protection layer can be SiO₂, Al₂O₃ or Fluoro-polymer etc.

The material of the substrate includes organic epoxy type FR4, FR5, BT, PCB (print circuit board), alloy or metal. The alloy includes Alloy42 (42% Ni-58% Fe) or Kovar (29% Ni-17% Co-54% Fe). Alternatively, the substrate could be glass, ceramic or silicon.

The material of thick dielectric layer includes silicone polymer base, polyimide base, silicone rubber type and epoxy resin type with photo-sensitive and adhesion properties once bonding the transparent cover and final curing.

### BRIEF DESCRIPTION OF THE DRAWINGS

FIG. 1 illustrates a cross-sectional view of CIS-CSP (CMOS Image Sensor-Chip Size Package) in accordance with one embodiment of the present invention.

FIG. 2 illustrates a cross-sectional view of CIS-CSP (CMOS Image Sensor-Chip Size Package) in accordance with one embodiment of the present invention.

FIG. 3 illustrates a top-view of CIS-CSP (CMOS Image Sensor-Chip Size Package) in accordance with one embodiment of the present invention.

FIGS. 4a-4e illustrate process steps for making panel level CIS chip scale package with protection transparent cover for the panel form (cross section).

FIG. 5 illustrates a cross section view of CIS module in accordance with one embodiment of the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

The present invention discloses a structure of Panel Level Package (PLP) utilizing a substrate having predetermined die through holes and contact (inter-connecting) through holes formed, and the contact metal pads on the upper side and the terminal metal pads on the lower side through the metal of through holes therein and a plurality of openings passing through the substrate. A wire bonding is connected between pads formed on an image sensor die and contact metal pads of the pre-formed substrate.

FIG. 1 illustrates a cross-sectional view of CIS-CSP (CMOS Image Sensor-Chip Scale Package) in accordance with one embodiment of the present invention. As shown in the FIG. 1, the structure of PLP includes a substrate 2 having predetermined die through holes 10 and contact (inter-connecting) through holes 6 formed therein, wherein the die through hole is to receive a die 16. Preferably, the die 16 is an image sensor die. Pluralities of the contact through holes 6 are created through the substrate 2 from upper surface to lower surface of the substrate 2, wherein the contact (inter-connecting) through holes 6 is surrounded (peripheral type) by the substrate 2. A conductive material will be re-filled into the through holes 6 for electrical communication. Terminal pads 8 are located on the lower surface of the substrate 2 and connected to the contact through holes 6 with conductive material. Contact conductive, such as metal, the contact pads 22 are located on the upper surface of the substrate 2 and also connected to the contact through holes 6 with conductive material. A terminal conductive pad 30 is configured on the lower surface of the substrate 2 to solder joining an external object. A wire bonding 24 is connected between pads 20 of the die 16 and contact metal pads 22 of the pre-formed substrate 2. A thick dielectric layer 38, for instance silicone polymer base material, is formed over the upper surface except the wire bonding 24 area, micro lens area 46 and the contact pads area 22 for adhesion with transparent cover; and core paste 50 is filled into the gap between the die 16 edge and sidewall of die through hole 10 and die back site as die attached materials. In one embodiment, material of the thick dielectric layer 38 comprises silicone polymer base type, polyimide base, silicone rubber type, epoxy resin type, elastic material, photosensitive material, and the thick dielectric layer 38 may be formed by coating or printing method with photo-sensitive properties.

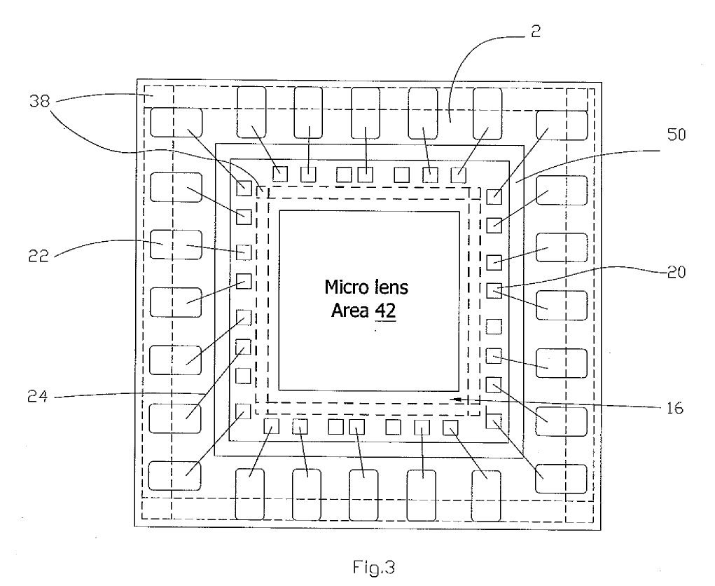

The die 16 is disposed within the die through hole 10 and fixed by the core paste (die attached) material 50 as the protection material for the backside of die. The core paste material 50 includes compound, epoxy resin, silicone rubber. The dimension of the width (size) of the die through hole 10 could be larger than the width (size) of the die 16 around 100 um each side. As know, contact pads (bonding pads) 20 are formed on the die 16 by a metal plating method. In one embodiment, the core paste 50 will be re-filled into gap of the through holes 10 (between die edge and the sidewall of die receiving through hole) and the back site of die 16 area as die attached material. In one embodiment, the core paste material 50 is an elastic material, photosensitive material or epoxy resin, silicone rubber material. Besides, a barrier layer 32 may be formed, such as by using a metal plating method, on side wall of the substrate 2 for better adhesion with the core paste 50. Die attached materials, such as core paste, 50 may be formed (printed) into the gap between die 16, the substrate 2 and the die back site. The wire bonding 24 is formed on the die 16, wherein the wire bonding 24 keeps electrically connected with the die 16 through the I/O pads 20 and the contact pads 22, thereby forming inter-connecting contact to contact the terminal pads 8. The thick dielectric layer 38 is formed the upper of the active surface of package to create an adhesive pattern (dotted lines shown as FIG. 3) by photo-sensitive process, it allows to open the I/O pads 20 and contact pads 22 for wire bonding and open the micro lens area. FIG. 3 illustrates a top-view of CIS-CSP (CMOS Image Sensor-Chip Scale Package) in accordance with one embodiment of the present invention. The thick dielectric layer 38 is adhered the transparent cover 36 to create a gap between the transparent cover 36 and the micro lens area 42. The aforementioned structure constructs LGA type (terminal pads in the peripheral of package) package.

It should be noted that the opening 46 is formed on the die 16 and a protection layer (film) 40 to expose the micro lens area 42 of the die 16 for CMOS Image Sensor (CIS). The protection layer (film) 40 can be formed over the micro lens on the micro lens area 42. The image sensor chips have been coated the protection layer (film) 40 on the micro lens area; the protection layer (film) 40 with the properties of water repellent and oil repellent that can away the particle contamination on the micro lens area. The thickness of protection layer (film) 40 is preferably around 0.1 um to 0.3 um and the reflection index close to the air reflection index 1. The process can be executed by SOG (spin on glass) skill and it can be processed in silicon wafer form. The materials of protection layer can be SiO₂, Al₂O₃ or Fluoro-polymer etc.

Finally, a transparent cover 36 with coating IR filter (optionally) is formed over the micron lens area 42 for protection. The transparent cover 36 is composed of glass, quartz, etc.

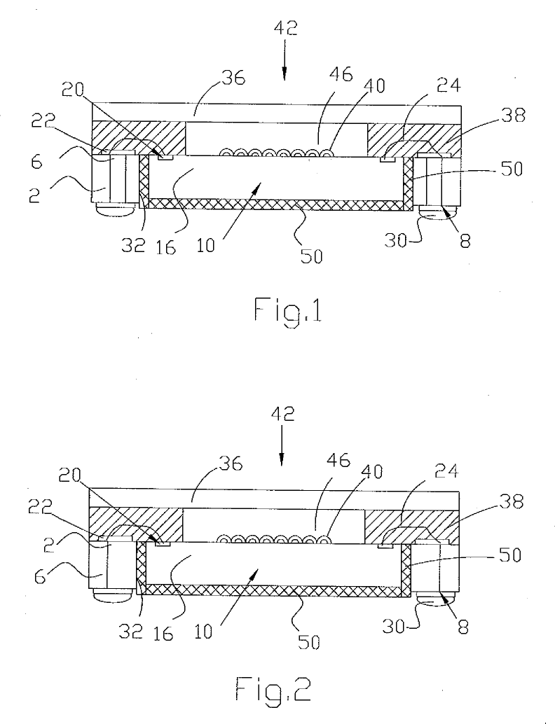

An alternative embodiment can be seen in FIG. 2, conductive balls 30 are formed under the contact terminal pads 8. This type is called BGA (Ball Grid Array) type. In FIG. 2, the contact (inter-connecting) through holes 6, for instance semi-spherical shape, is formed in a scribe line area passing through the substrate 2, the semi-spherical sharp for inter-connecting through holes 6 also can be formed in the sidewall area of the die receiving through hole (not shown), the other parts are similar to FIG. 1; therefore, the reference numbers of the similar parts are omitted. The contact through holes 6 is in the scribe line; therefore each package has half through hole such that improve the solder join quality and reduce the foot print. Preferably, the material of the substrate 2 is organic substrate likes FR5, FR4, BT (Bismaleimide triazine), PCB with defined opening or Alloy42 with pre etching circuit. The organic substrate with high Glass transition temperature (Tg) are epoxy type FR5 or BT (Bismaleimide triazine) type substrate for better process performance. The Alloy42 is composed of 42% Ni and 58% Fe. Kovar can be used also, and it is composed of 29% Ni, 17% Co, 54% Fe. The glass, ceramic, silicon can be used as the substrate due to lower CTE.

The substrate could be rectangular type such as panel form, and the dimension could be fit into the wire bonder machine. As shown in FIGS. 1 and 2, the wire bonding 24 fans out of the die and communicates with the contact pads 22 and I/O metal pads 20. It is different from the prior art technology which stacks layers over the die, thereby increasing the thickness of the package. However, it violates the rule to reduce the die package thickness. On the contrary, the terminal pads 8 are located on the surface that is opposite to the die pads side. The communication traces are penetrates through the substrate 2 via the contact through holes 6 and leads the signal to the terminal pads 8. Therefore, the thickness of the die package is apparently shrinkage. The package of the present invention will be thinner than the prior art. Further, the substrate is pre-prepared before package. The die through hole 10 and the contact through holes 6 are pre-determined as well. Thus, the throughput will be improved than ever. The present invention discloses a PLP without stacked built-up layers over the wire bonding.

The process steps for making CIS chips package for the panel/wafer form includes coating a protection layer (thin film) of thickness 0.1˜0.3 u with water and oil repellency, and then curing the protection layer. The protection layer (film) is performed by a plasma etching (or wet etching) with through hole mask to create (open) bonding pads area. The wafer is lapped and dicing sawed to separate, for instance by sawing the wafer substrate at a scribe line, to be plurality of individual units (CIS chips). The scribe line is located at the etched area which is defined between the units for separating each of the units.

Next, the desired CIS dice are picked and placed on the tools with pattern glues. The substrate with die through hole and contacting through holes is bonded onto the tool with pattern glues. Die attached materials, such as core paste, is printed into the gap between die and substrate and the die back site. Finally, the “Panel” wafer is separated from the tool and clean the active surface of the CIS chips package.

In the present invention, the thick dielectric layer 38 formed over the active surface of panel to create adhesive patterns by employing printing or coating, preferable photo-sensitive type, to create a space for exposing micro lens area with a gap. It should be noted that the thick dielectric layer 38 surrounds the micro lens area to expose micro lens area 46, bonding pads 20 area and the contact pads 22 area of substrate, and thereby the transparent panel 36 protecting micro lens from contaminations.

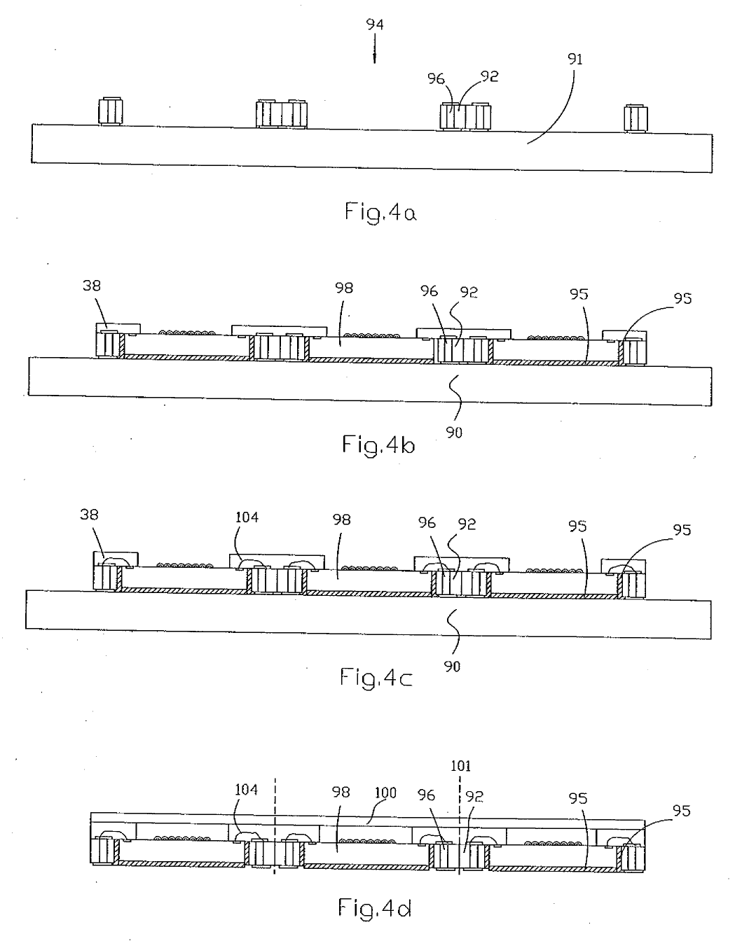

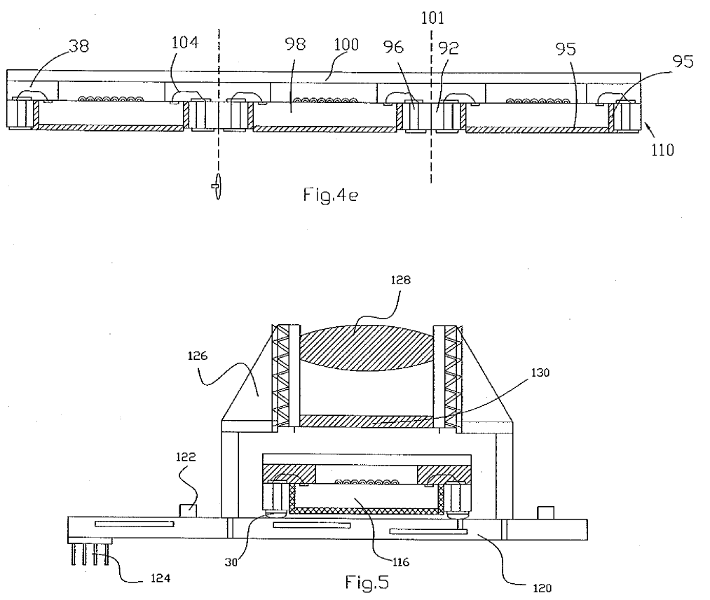

FIGS. 4a-4e illustrate process steps for making panel level CIS chips scale package with protection transparent cover for the panel form (cross section). The process for the present invention includes providing an alignment tool (chips redistributed tool) 91 with alignment pattern formed thereon. Then, the pattern glues (elastic adhesion materials) is printed (coated) on the tool 91 (be used for sticking the active surface of dice—do not show in the drawing), followed by using a pick and place fine alignment system with die bonding function to re-distribute the known good dice on the tool 91 with desired pitch. The pattern glues will stick the chips on the tool 91. Subsequently, a substrate 92 with die through holes 94 and contact through hole 96, and contact pad 22 on the upper side and terminal pads 8 on the lower side is provided on the tool 91, shown in FIG. 4a. A conductive material will be re-filled into the through holes 96 for electrical communication (pre-formed substrate). Next, a die 98, for instant die of FIG. 1 and FIG. 2, with micro lens formed thereon is inserted and attached stuck into the die through holes 94 of the substrate 92 by the pattern glues at die active side. Then, die attached materials, such as core paste, 95 may be formed (printed) into the gap between die 98, the substrate 92 and the die back site, after the curing, to separate the tool 91 and panel. The next step is to clean the active surface of panel and temperate bonding on the supporting carrier 90 as shown in FIG. 4b. Next, coating the thick dielectric layer 38 and using the exposure and developing process are to open the micro lens area 46, bonding pads area 20 and the contact pads area 22; shown in FIG. 3 and FIG. 4b. Then, a wire bonding 104 is formed to connect between pads of the die 98 and contact metal pads of the pre-formed substrate 92, shown in FIG. 4c. The active surface (micro lens area) of the CIS chips scale package is then cleaned. Subsequently, a glass 100 which is substantially same panel form size with scribe line 101 is bonded on to the “Panel” with thick dielectric layer 38 by an alignment and vacuum. The scribe line is inscribed by a diamond saw scriber. The thick dielectric layer 38 is cured to adhesive the glass 100 and panel. The panel supporting carrier 90 is separated from the panel after vacuum curing, shown in FIG. 4d.

After the ball placement or solder paste printing on the terminal metal pads, the heat re-flow procedure is performed to re-flow on the substrate side to form the solder bumps (for BGA type). The testing is executed. Panel level final testing is performed by using vertical probe card. After the testing, a panel 110 is mounted on the blue tape and cutting the panel from terminal metal site which is only cut the substrate site from the bottom of the substrate. Finally, the glass 100 is broke along the scribe line 101 to singulate and to separate the package into individual units, shown in FIG. 4e. Then, the packages are respectively picked and placed the package (device) on the tray or tape and reel.

Referring to FIG. 5, it is an individual CMOS image sensor module by using CIS-CSP in this present invention. The die comprises CMOS sensor or CCD image sensor. Terminal conductive pads 30 of CIS-CSP 116 are connected (by SMT process—soldering join) to the connection pads of a flex printed circuit board 120 (FPC) with connector 124 (for connecting with mother board) formed thereon. CIS-CSP 116 is for example unit package of FIG. 1 and FIG. 2. Then, a lens 128 is disposed above the transparent cover (glass) 36 of CIS-CSP 116 to allow the light to pass through. As the same, a micro lens may be formed on the micro lens area, and a gap is created between the die 16 and the transparent cover (glass) 36. A lens holder 126 is fixed on the printed circuit board 120 to hold the lens 128 on top of the CIS-CSP 116. A filter 130, such as IR filter, is fixed to the lens holder 126. Alternatively, the filter 130 may comprise a filtering layer, for example IR filtering layer, formed upper or lower surface of the transparent cover (glass) 36 to act as a filter. In one embodiment, IR filtering layer comprises TiO2, light catalyzer The transparent cover (glass) 36 may prevent the micro lens from particles containment. The user may use liquid or air flush to remove the particles on the transparent cover (glass) 36 without damaging the micron lens. Moreover, a passive device 122 can be configured on the printed circuit board 120.

Hence, the advantages of the present invention are:

The substrate is pre-prepared with pre-form through hole and wiring circuit; it can generates the super thin package due to die insert inside the substrate, thickness under 200 um (from image sensor surface); it can be used as stress buffer releasing area by filling silicone rubber or liquid compound materials to absorb the thermal stress due to the CTE difference between silicon die (CTE—2.3) and substrate (FR5/BT—CTE—16)). The packaging throughput will be increased (manufacturing cycle time was reduced) due to apply the simple process: die bonding, wire bonding, protection layer and sawing, it is due to the lower pin count structure of image sensor chips. The terminal pads are formed on the opposite surface to the dice active surface (pre-formed). The dice placement process is the same as the current process—die bonding. No particles contamination during process to module is produced for the present invention which is put the glass cover in wafer form once it is completed at fab. The surface level of die and substrate can be the same after die is attached on the die through hole of substrate. The package is cleanable due to glass cover on the micro lens. The chip scale package has size around chip size plus 0.5 mm/side. The reliability for both package and board level is better than ever, especially, for the board level temperature cycling test, it was due to the CTE of substrate and PCB mother board are identical, so, no thermal mechanical stress be applied on the solder bumps/balls. The cost is low and the process is simple. The manufacturing process can be applied fully automatic especially in module assembly by using the SMT process. It is easy to form the combo package (dual dice package). The LGA type package has peripheral terminal pads for SMT process. It has high yield rate due to particles free, simple process, fully automation.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A structure of image sensor package, comprising:
a substrate with a die through hole and contact through holes structure formed there through, wherein terminal pads are formed under said contact through hole structure and contact pads are formed on a upper surface of said substrate;
a die having a micro lens area disposed within said die through hole;
a dielectric layer formed on said die and said substrate except the micro lens area, bonding pads area and contact pads area;
a wire bonding formed on said die and said substrate, wherein said wire bonding is coupled to said die and said contact pad;
a core paste material formed into the gap between said die edge and the sidewall of said die through hole of said substrate and said die back site; and
a transparent cover disposed on said die and said dielectric layer by adhesion to create a gap between said transparent cover.

2. The structure of claim 1, farther comprising conductive bumps coupled to said terminal pads.

3. The structure of claim 1, wherein material said core paste material includes compound, epoxy resin, silicone rubber.

4. The structure of claim 1, wherein said dielectric layer comprises silicone polymer base, polyimide base, silicone rubber type, epoxy resin type, elastic material, photosensitive material.

5. The structure of claim 1, further comprising a barrier layer formed on the sidewall of said die through hole of said substrate.

6. The structure of claim 5, wherein said barrier layer comprises a metal layer.

7. The structure of claim 1, wherein said contact through holes structure includes the semi-spherical sharp in the scribe line area or sidewall area of die through hole of said substrate.

8. The structure of claim 1, wherein the material of said substrate includes epoxy type FR5, FR4.

9. The structure of claim 1, wherein the material of said substrate includes BT.

10. The structure of claim 1, wherein the material of said substrate includes PCB (print circuit board).

11. The structure of claim 1, wherein the material of said substrate includes alloy or metal.

12. The structure of claim 1, wherein the material of said substrate includes glass, silicon, ceramic.

13. The structure of claim 1, further comprising a protection layer formed on said micro lens area to protect the micro lens away the particles contamination.

14. The structure of claim 13, wherein materials of said protection layer includes SiO₂, Al₂O₃ or Fluoro-polymer.

15. The structure of claim 13, wherein said protection layer with water repellent and oil repellent properties.

16. A method for forming semiconductor device package, comprising:
providing a substrate with die through holes and contact through holes structure formed there through on a tool, wherein terminal pads are formed under said contact through hole structure and contact pads are formed on a upper surface of said substrate;
using a pick and place fine alignment system to re-distribute known good dice said image sensor chips on said tool with desired pitch;
filling core paste into the gap between said die edge and the sidewall of said die through hole of said substrate, and said die back site and separating said tool;
forming a dielectric layer to cover an active surface except the micro lens of said chip, the bonding pads of said chip and the contact pads of said substrate;
forming a wire bonding to couple between said chip and contact pad of said substrate;
bonding a transparent cover with inscribed lines on a panel over said dielectric layer;
cutting said panel from the terminal metal site of said substrate; and
separating said transparent cover along said scribe lines to singulate and separate the package into individual units.

17. The method of claim 16, further comprising forming a protection layer on micro lens area of said image sensor chip to protect the micro lens away the particles contamination.

18. The method of claim 16, further comprising a step of printing a solder paste on said terminal pads and re-flowing said paste to form the solder bumps.

19. A structure of image sensor module, comprising,
a flex print circuit board (FPC) with wiring circuit, connection pads and connector;
a solder paste to solder said connection pads of said FPC and the terminal pads of a substrate;
wherein said substrate has die through holes and contact through holes structure formed there through, wherein said terminal pads are formed under said contact through hole structure and contact pads are formed on a upper surface of said substrate;
a die having a micro lens area disposed within said die through hole;
a dielectric layer formed on said die and said substrate except the micro lens area, bonding pads area and contact pads area;
a wire bonding formed on said die and said substrate, wherein said wire bonding is coupled to said die and said contact pad;
a core paste material formed into the gap between said die edge and the sidewall of said die through hole of said substrate and said die back site;
a transparent cover disposed on said die and said dielectric layer by adhesion to create a gap between said transparent cover; and
a lens holder with lens fixed on said FPC and disposed above said transparent cover to allow the light passing through said micro lens area.

20. The structure of claim 19, further comprising passive components soldering join on said FPC.
